(19) United States
(12) Patent Application Publication
(10) Pub. No.: US 2014/0049921 A1
(43) Pub. Date: Feb. 20, 2014

(54) FASTENING STURCTURE AND DISLAY MODULE USING THE SAME

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: CHIH-HUNG TSAI, New Taipei (TW); MING GUO, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/869,415

(22) Filed: Apr. 24, 2013

(30) Foreign Application Priority Data
Aug. 15, 2012 (CN) 2012102897366

(51) Int. Cl. H05K 7/14

(52) U.S. Cl. CPC H05K 7/1401
USPC 361/728; 403/14

(57) ABSTRACT

A fastening structure includes a first main body, a second main body, a first fixing member protruding from the first main body, and a second fixing member protruding from the second main body. The first fixing member includes a first clamping element and a second clamping element. The second fixing member includes a first positioning element and a second positioning element. The first positioning element is limited by the first clamping element to prevent the first main body from moving with respect to the second main body in first directions, the second positioning element is limited by the second clamping element to prevent the first main body from moving with respect to the second main body in second directions cooperating with the first the directions to contain all directions in the reference plane.

### BACKGROUND

1. Technical Field

The present disclosure relates to fastening structures, and particularly to a fastening structure for fastening a bezel of a display module of a notebook computer.

2. Description of Related Art

A display module of a notebook computer includes a cover, a bezel, an LCD panel, and a plurality of screws. In assembling of the notebook computer, the LCD panel and the bezel are both mounted to the cover by a plurality of screws. However, this way of securing the bezel is unsightly.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded view of a fastening structure with a first securing member and a second securing member.

FIG. 2 is assembled view of the fastening structure in FIG. 1.

FIG. 3 is across-sectional view of the first securing member and a second securing member in FIG. 1 in accordance with a first embodiment.

FIG. 4 is a crossing view of the first securing member and a second securing member in FIG. 1 in accordance with a second embodiment.

FIG. 5 is a display module using the fastening structure in FIG. 1.

### DETAILED DESCRIPTION

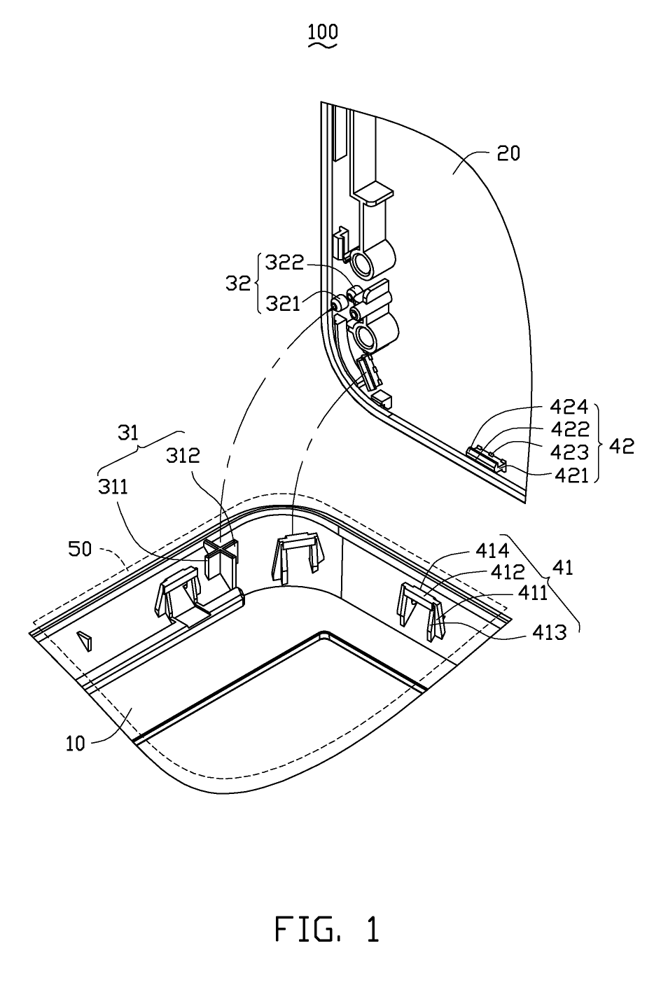

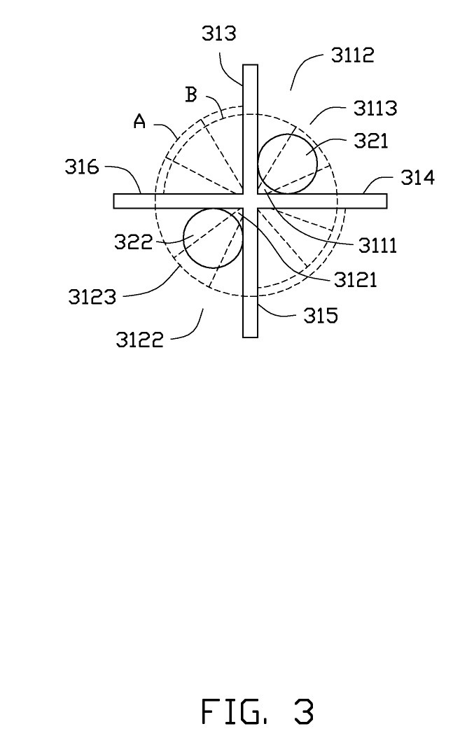

FIGS. 1 and 3 show a fastening structure 100 of one embodiment. The fastening structure 100 includes a first main body 10, a second main body 20, a first fixing member 31, a second fixing member 32, a first gripping member 41, and a second gripping member 42. The first fixing member 31 and the first gripping member 41 are arranged on the first member 10. The second fixing member 32 and the second gripping member 42 are arranged on the second member 20.

The first fixing member 31 is integrated with the first main body 10. The first fixing member 31 extends from the first member 10 toward the second main body 20. The first fixing member 31 includes a first clamping element 311 and a second clamping element 312. The first clamping element 311 includes a first rib 313, and a second rib 314. The first rib 313 and the second rib 314 are arranged forming an angle. As a result, the first clamping element 311 forms a first limiting portion 3111 and a first open portion 3112 opposite to the first limiting portion 3111, and the first open portion 3112 defines a first opening 3113. The second clamping element 312 includes a third rib 315, and a second rib 316. The third rib 315 and the fourth rib 316 are arranged forming an angle. As a result, the second clamping element 312 forms a second limiting portion 3121 and a second open portion 3112 opposite to the second limiting portion 3121, and the second open portion 3112 defines a second opening 3123. The third rib 315 is connected to the first rib 313, and the third rib 315 and the first rid 313 are arranged in a first straight line. The fourth rib 316 is connected to the second rib 314, and the fourth rib 316 and the second rid 314 are arranged in a second straight line. The first straight line and the second straight line form a reference plane 50. The second limiting portion 3121 is connected to the first limiting portion 3111, and the first limiting portion 3111 and the second limiting portion 3121 are located between the first open portion 3112 and the second open portion 3122.

The second fixing member 32 is integrated with the second main body 20, and the second fixing member 32 corresponds to the first fixing member 31. The second fixing member extends from the second main body 20 along a direction perpendicular with the reference plane 50, toward the first fixing member 31. The second fixing member includes a first positioning element 321 and a second positioning element 322 to be received in the first opening 3113 and the second opening 3123. The first positioning element 321 and the second positioning element 322 are separated from each other. Sizes of the first positioning element 321 and the second positioning element 322 are smaller than sizes of the first opening 3113 and the second opening 3123, as a result, the first positioning element 321 and the second positioning element 322 are easily received in the first opening 3113 and the second opening 3123. In this embodiment, the first positioning element 321 and the second positioning element 322 are two separate cylinders.

The first gripping member 41 is integrated with the first main body 10. The first gripping member 41 extends from the second main body along the direction perpendicular with the reference plane 50, towards the second main body 20. The first gripping member 41 includes two separate vertical arms 411 perpendicular with the reference plane 50, and a cross arm 412 parallel to the reference plane 50, and two first strengthening ribs 413. Two first strengthening ribs 413 are connected to the vertical arms 411 and the first main body 10 to enable the two vertical arms 411 firmly connected to the first main body 10. The cross arm 412 includes a first incline guiding surface 414.

The second gripping member 42 is integrated with the second main body 20. The second gripping member 42 extends from the second main body 20 along the direction perpendicular with the reference plane 50 towards the first gripping member 41. The second gripping member 42 includes a main part 421 and a hook 422 extending from one end of the main part 421 away from the second main body 20 along the direction parallel to the reference plane 50, and two second strengthening ribs 423. The second strengthening ribs 423 are connected to the main part 421 and the second main body 20 to enable the two vertical arms 411 to firmly connect to the first main body 10. The hook includes a second guiding incline guiding surface 424, the second guiding surface 424 cooperates with the first guiding surface 414 to enable the hook 422 to catch on the cross arm 412. As a result, the first main body 10 and the second main body 20 are prevented from moving in a direction perpendicular with the reference plane 50. In other words, the first main body 10 and the second main body 20 are fastened in the direction perpendicular with the reference plane 50.

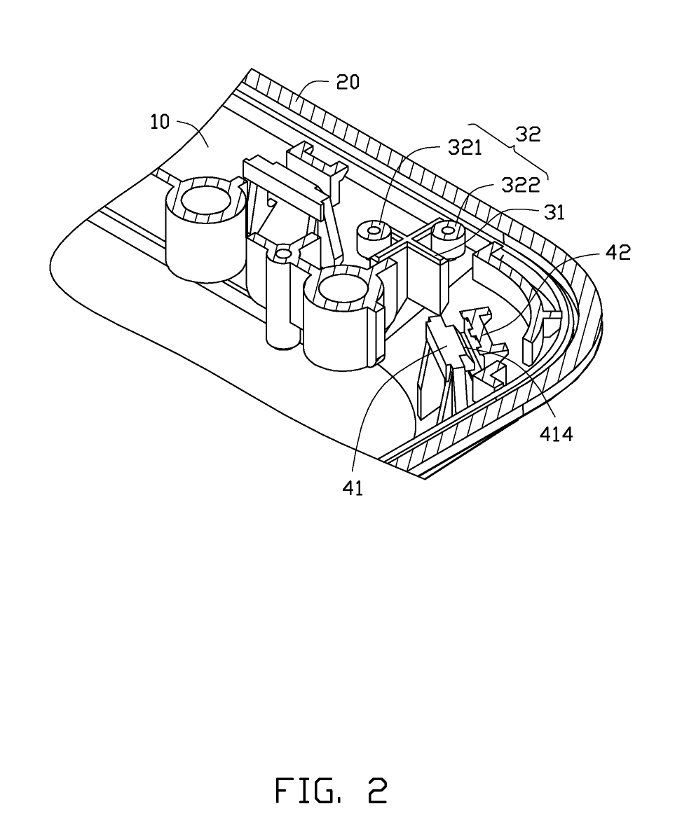

FIGS. 2 and 3 show that when the second main body 20 is to be fastened to the first main body 10, the first fixing element 321 and the second fixing element 322 are placed into the first limiting portion 3111 and the second limiting portion 3121. The sizes of the first positioning element 321 and the second positioning element 322 are smaller than the sizes of the first opening 3113 and the second opening 3123. As such the first positioning element 321 and the second positioning element 322 can be placed into the limiting portion 3111 and the limiting portion 3121 via the first opening 3113 and the second opening 3123. As a result, the first positioning element 321 is limited by the first clamping element 311 and the second position element 322 which prevents the first main body 10 from moving laterally with respect to the second body 20. The second positioning element 322 is limited by the second clamping element 312 and the first position element 321 which prevents the first main body 10 from moving laterally with respect to the second body 20. In particular, the first position element 321 is limited by the first clamping element 311 and the second position element 322 to be prevented from moving in first directions of the reference plane 50. The second position element 322 is limited by the first positioning element 321 to be prevented from moving in second directions of the reference plane 50. The first directions A are different from the second directions B, and the first directions A cooperate with the directions B to contain all directions of the reference plane 50. As a result, the first main body 10 is prevented from moving with respect to the second main body 20 in any one direction of the reference plane 50.

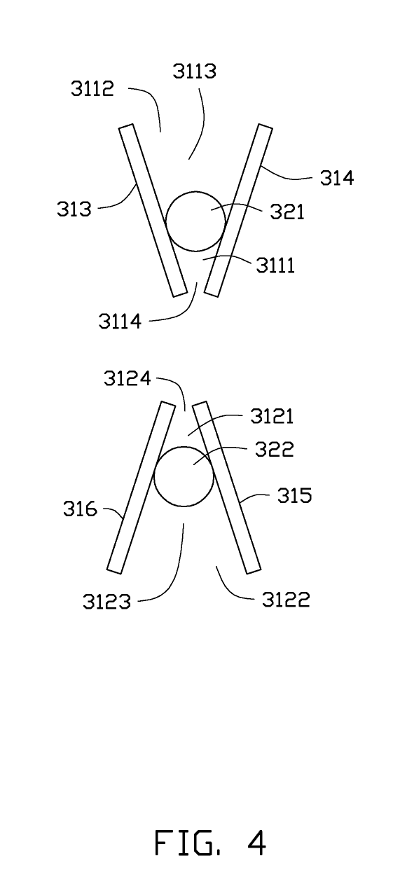

FIG. 4 shows that in another embodiment, the first rib 313 and the third rib 315 are parallel to each other, the second rib 314 and the fourth rib 316 are parallel to each other. The first rib 313 and the second rib 314 are separated from each other, and the first rib 313 and the second rib 314 are set at an angle to form the first limiting portion 3111 and the first open portion 3112. The third rib 315 and the fourth rib 316 are separated from each other to form the second limiting portion 3121 and the second open portion 3122. The first limiting portion 3111 and the second limiting portion 3132 are separated from each other. There is a third opening 3114 between the first rib 313 and the second rib 314. There is a fourth opening 3124 between the third rib 315 and the fourth rib 316. The sizes of the third opening 3114 and the fourth opening 3124 are smaller than the sizes of the first positioning element 321 and the second positioning element 322, as a result, the first positioning element 321 and the second positioning element 322 are limited by the first limiting portion 3111 and the second limiting portion 3132.

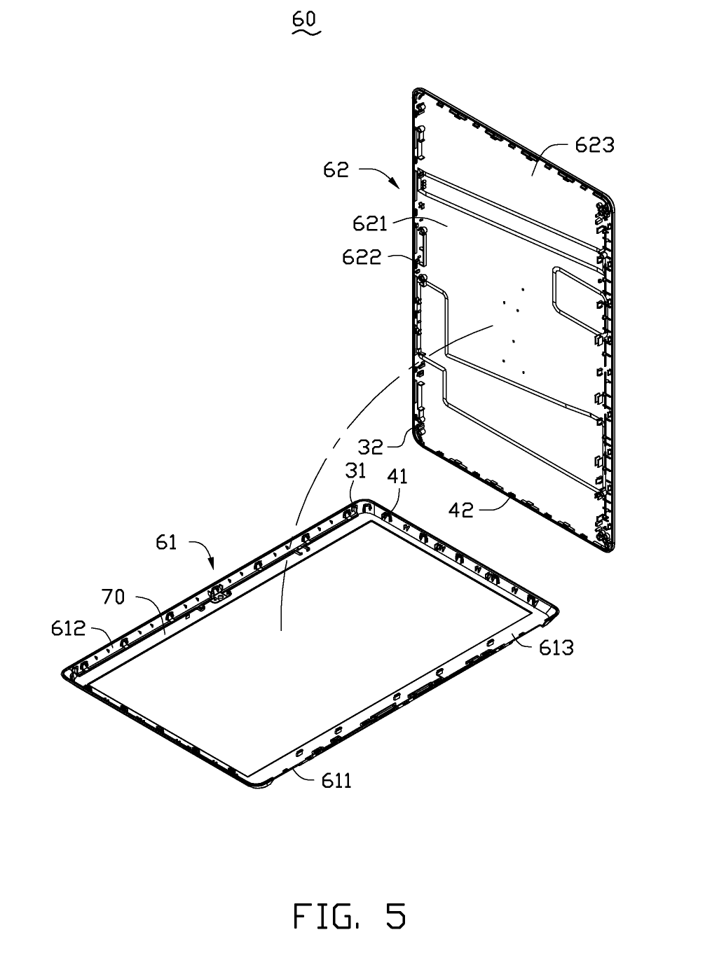

FIG. 5 shows a display module 60 of a notebook computer using the above fastening structure 100. The display module 60 includes a bezel 61, a cover 62, a display panel (not shown), and a plurality of circuit boards. The bezel 61 is fastened to the cover 62 to mount the display panel between the bezel 61 and the cover 62 via four fastening structures 100. In this embodiment, the bezel 61 is arranged as the first main body 10 of the fastening structure 100. The cover 62 is arranged as the second main body 20 of the fastening structure 100.

The bezel 61 includes a rectangular front side 611, and a side wall 612 extending from edge of the front side 611 towards the cover 62. The front side 611 defines an opening 610 to form four rims 613 connected end to end.

The size of the cover 62 matches the bezel 61. The cover 62 includes a rectangular bottom wall 621, and a flange 622 extending from edges of the bottom wall 621 towards the bezel 61.

Four first fixing members 31 are integrated with the bezel 61, and the first fixing members 31 extending from the side wall 612 towards the cover 62. The first fixing members 31 are arranged at four corners of the bezel 61. Four second fixing members 32 are integrated with the cover 62, and the second fixing members 32 extend from the inner surface 623 of bottom wall 621 toward the bezel 61. The second fixing members 32 are arranged at four corners of the cover 62.

The first gripping member 41 is integrated with the bezel 61, and first clamping members 41 extend from the side wall 612 towards the cover 62. Four first clamping members 41 are arranged on four corners of the side wall 612. Four second clamping members 42 are integrated with the cover 62, and the second clamping members 42 extend from the inner surface 623 of the bottom wall 621 towards the corresponding first clamping members 41. The second clamping members 42 are arranged at the corners of the side wall 612.

When the cover is covering the bezel 61, the flange 622 and the side wall 612 are engaged so that the bezel 61 and cover 62 cooperate to form a space to receive the first fixing members 31, the second fixing members 32, the first clamping members 41 and the second gripping members 42, the display panel, and circuit boards. The first fixing member 31 and the second fixing member 32 cooperate to prevent the bezel 61 and the cover 62 from moving in any direction on the reference plane 50. The first clamping members 41 and the second clamping members 42 cooperate to prevent the bezel 61 and the cover 62 from moving in any direction perpendicular with the reference plane 50. As a result, the bezel 61 and the cover 62 are combined together.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A fastening structure, comprising:
a first main body;
a second main body;
a first fixing member protruding from the first main body, the first fixing member comprising a first clamping element and a second clamping element; and
a second fixing member protruding from the second main body, the second fixing member comprising a first positioning element and a second positioning element;
wherein the first positioning element is limited by the first clamping element to prevent the first main body from moving with respect to the second main body in first directions of the reference plane, the second positioning element is limited by the second clamping element to prevent the first main body from moving with respect to the second main body in second directions of the reference plane, the first directions are different from the second directions, and the first directions cooperate with the second directions to contain all directions of the reference plane to prevent the first main body from moving with respect to the second main body in a reference plane.

2. The fastening structure of claim 1, wherein the first clamping member comprises a first limiting portion, and a first open portion defining a first opening opposite to the first limiting portion; the second clamping member comprises a second limiting portion, and a second open portion defining a second opening opposite to the second limiting portion; the first limiting portion and the second limiting portion are positioned between the first open portion and the second opening portion, the first positioning element is received in the first clamping member via the first opening, and the first positioning element is limited by the first limiting portion, the second position element is received in the second clamping member via the second opening, and the second positioning element is limited by the second limiting portion.

3. The fastening structure of claim 2, wherein sizes of the first positioning element and the second positioning element are smaller than sizes of the first opening and the second opening.

4. The fastening structure of claim 2, wherein the first limiting portion is connected to the second limiting portion.

5. The fastening structure of claim 1, wherein the first fixing element comprises a first ribs, a second rib, a third rib, and a fourth rib, the first rib and the second rib are arranged at an angle to form the first clamping element; the third rib and the fourth rib are arranged at an angle to from the second clamping element.

6. The fastening structure of claim 5, wherein the first rib and the third rib are arrange in a first straight line, the second rib and the fourth rib are arranged in a second straight line, the first straight line intersect the second straight line at a point.

7. The fastening structure of claim 6, wherein the first limiting portion is connected with the second limiting portion at the point.

8. The fastening structure of claim 6, wherein the first limiting portion defines a third opening, the second limiting portion defines a fourth opening, the sizes of the third opening and the fourth opening are smaller than the first positioning member and the second positioning member.

9. The fastening structure of claim 6, wherein the first limiting portion defines a third opening, the second limiting portion defines a fourth opening, the sizes of the third opening and the fourth opening are smaller than the first positioning member and the second positioning member.

10. The fastening structure of claim 6, further comprising a first gripping member protruding from the first main body, and a second gripping member protruding from the second main body, the first gripping member and the second gripping member being engaged to prevent the first main body from moving with respect to the second main body in a direction perpendicular with the reference plane.

11. A display module, comprising:
a bezel;
a cover; and
at least one fastening structure comprising:
a first fixing member protruding from the bezel, the first fixing member comprising a first clamping element and a second clamping element; and
a second fixing member protruding from the cover, the second fixing member comprising a first positioning element and a second positioning element;
wherein the first positioning element is limited by the first clamping element to prevent the bezel from moving with respect to the cover in first directions of the reference plane, the second positioning element is limited by the second clamping element to prevent the bezel from moving with respect to the cover in second directions of the reference plane, the first directions are different from the second directions, and the first directions cooperate with the second directions to contain all directions of the reference plane to prevent the bezel moving with respect to the cover in the reference plane.

12. The display module of claim 11, wherein the bezel comprises four corners, the cover comprises four corners, the number of the at least one fastening structure is four, each first fixing member protruding from each corner of the bezel, each second fixing member protruding from each corner.

13. The display module of claim 11, wherein the first clamping member comprises a first limiting portion, and a first open portion defining a first opening opposite to the first limiting portion; the second clamping member comprises a second limiting portion, and a second open portion defining a second opening opposite to the second limiting portion; the first limiting portion and the second limiting portion are positioned between the first open portion and the second opening portion, the first positioning element is received in the first clamping member via the first opening, and the first positioning element is limited by the first limiting portion, the second position element is received in the second clamping member via the second opening, and the second positioning element is limited by the second limiting portion.

14. The display module of claim 13, wherein the first limiting portion is connected to the second limiting portion.

15. The display module of claim 11, wherein the first fixing element comprises a first ribs, a second rib, a third rib, and a fourth rib, the first rib and the second rib are arranged at an angle to form the first clamping element; the third rib and the fourth rib are arranged at an angle to form the second clamping element.

16. The display module of claim 15, wherein the first rib and the third rib are arrange in a first line, the second rib and the fourth rib are arranged in a second line, the first straight line intersect the second straight line at a point.

17. The display module of claim 16, wherein the first limiting portion is connected to the second limiting portion at the intersecting point of the first line and the second line.

18. The display module of claim 16, wherein the first limiting portion defines a third opening, the second limiting portion defines a fourth opening, the sizes of the third opening and the fourth opening are smaller than the sizes of first positioning member and the second positioning member.

19. The display module of claim 16, wherein the first limiting portion defines a third opening, the second limiting portion defines a fourth opening, the sizes of the third opening and the fourth opening are smaller than the first positioning member and the second positioning member.

20. The display module of claim 11, further comprising a first gripping member protruding from the first main body, and a second gripping member protruding from the second main body, the first gripping member and the second gripping member being engaged to prevent the first main body from moving with respect to the second main body in a direction perpendicular with the reference plane.
